(19) United States
(12) Patent Application Publication
(10) Pub. No.: US 2010/0219492 A1
(43) Pub. Date: Sep. 2, 2010

(54) LOW SWITCHING FIELD LOW SHAPE SENSITIVITY MRAM CELL

(76) Inventor: Jannier Maximo Roiz Wilson, Santa Clara, CA (US)

Correspondence Address: HAHN AND MOODLEY, LLP, 548 Market Street, San Francisco, CA, 94104, US

(21) Appl. No.: 12/714,395

(22) Filed: Feb. 26, 2010

Related U.S. Application Data
(60) Provisional application No. 61/156,276, filed on Feb. 27, 2009.

(51) Int. Cl. H01L 29/82; H01L 21/00

(52) U.S. Cl. 257/421; 438/3; 257/E21.001; 257/E29.323

(57) ABSTRACT

Disclosed is a Magnetic Tunnel Junction (MTJ) stack usable in a nonvolatile magnetic memory array of MTJ stacks, the MTJ stack comprising: a) a fixed ferromagnetic layer having its magnetic moment fixed in a preferred direction in the presence of an applied magnetic field caused by a current; b) an insulating tunnel barrier layer in contact with the fixed ferromagnetic layer; and c) a free ferromagnetic layer in contact with the insulating tunnel barrier layer, the free ferromagnetic layer comprising a synthetic anti-ferromagnet (SAF) stack comprising i) at least three ferromagnetic layers arranged anti-ferromagnetically relative to the next, and ii) at least two coupling layers, wherein the at least three ferromagnetic layers are separated by the at least two coupling layers.

This application claims the benefit of priority to U.S. Provisional application 61/156,276 which was filed Feb. 27, 2009.

### TECHNICAL FIELD OF THE DISCLOSURE

Embodiments of the disclosure relate to Magnetic Random Access Memory (MRAM).

### BACKGROUND OF THE DISCLOSURE

Magnetic random access memory (MRAM) cells comprise a Magnetic Tunnel Junction (MTJ) stack located at an intersection of two metal wires. Several layers of an MTJ stack are composed of ferromagnetic material. In the MTJ stack, the magnetization of some magnetic layers are able to flip under the effect of an applied magnetic field (these are the called “free ferromagnetic layers or free layers”), while others are not (these are the called “fixed ferromagnetic layers or fixed layers”). The metal wires provide the magnetic field capable of flipping the magnetization in the free ferromagnetic layer by simultaneously passing electric current through them. MRAM cells have two stable magnetization configurations that can be selected by flipping the magnetization from one configuration to the other. One configuration represents a memory state “1” and the other a state “0”.

An MTJ stack may have different electric resistance depending on the orientation of the magnetization in the free ferromagnetic layer relative to the magnetization in the fixed ferromagnetic layer. Normally, MRAM uses the parallel and anti-parallel magnetization configurations to provide two very different values of resistance (low and high, respectively) to represent logical values “1” or “0”. A reading circuitry connected to each cell senses the resistance of the cell by passing current through it.

Conventional MRAM approaches have a free ferromagnetic layer composed of either a single magnetic layer or a synthetic anti-ferromagnet (SAF) layer. The SAF layer has the advantage over the single magnetic layer of substantially reducing edge domains in the cells so that switching field variations are considerably reduced.

### SUMMARY OF THE DISCLOSURE

In one aspect, the present disclosure provides a Magnetic Tunnel Junction (MTJ) stack usable in a nonvolatile magnetic memory array of MTJ stacks, the MTJ stack comprising: a) a fixed ferromagnetic layer having its magnetic moment fixed in a preferred direction in the presence of an applied magnetic field caused by a current; b) an insulating tunnel barrier layer in contact with the fixed ferromagnetic layer; and c) a free ferromagnetic layer in contact with the insulating tunnel barrier layer, the free ferromagnetic layer comprising a synthetic anti-ferromagnet (SAF) stack comprising i) at least three ferromagnetic layers arranged anti-ferromagnetically relative to the next, and ii) at least two coupling layers, wherein the at least three ferromagnetic layers are separated by the at least two coupling layers.

In another aspect, the present disclosure provides a nonvolatile magnetic memory comprising: an array of Magnetic Tunnel Junction (MTJ) stacks, wherein each Magnetic Tunnel Junction (MTJ) stack comprising a) a fixed ferromagnetic layer having its magnetic moment fixed in a preferred direction in the presence of an applied magnetic field caused by a current, b) an insulating tunnel barrier layer in contact with the fixed ferromagnetic layer, and c) a free ferromagnetic layer in contact with the insulating tunnel barrier layer, the free ferromagnetic layer comprising a synthetic anti-ferromagnet (SAF) stack comprising i) at least three ferromagnetic layers arranged anti-ferromagnetically relative to the next, and ii) at least two coupling layers, wherein the at least three ferromagnetic layers are separated by the at least two coupling layers.

In yet another aspect, the present disclosure provides an electronic device comprising: a nonvolatile magnetic memory having an array of Magnetic Tunnel Junction (MTJ) stacks, wherein each Magnetic Tunnel Junction (MTJ) stack comprising a) a fixed ferromagnetic layer having its magnetic moment fixed in a preferred direction in the presence of an applied magnetic field caused by a current, b) an insulating tunnel barrier layer in contact with the fixed ferromagnetic layer, and c) a free ferromagnetic layer in contact with the insulating tunnel barrier layer, the free ferromagnetic layer comprising a synthetic anti-ferromagnet (SAF) stack comprising i) at least three ferromagnetic layers arranged anti-ferromagnetically relative to the next, and ii) at least two coupling layers, wherein the at least three ferromagnetic layers are separated by the at least two coupling layers.

In yet another aspect, the present disclosure provides a method for fabricating an Magnetic Tunnel Junction (MTJ) stack comprising; a) introducing a fixed ferromagnetic layer having its magnetic moment fixed in a preferred direction in the presence of an applied magnetic field caused by a current, b) providing an insulating tunnel barrier layer in contact with the fixed ferromagnetic layer, and c) positioning a free ferromagnetic layer in contact with the insulating tunnel barrier layer, the free ferromagnetic layer comprising a synthetic anti-ferromagnet (SAF) stack comprising i) at least three ferromagnetic layers arranged anti-ferromagnetically relative to the next, and ii) at least two coupling layers, wherein the at least three ferromagnetic layers are separated by the at least two coupling layers.

### BRIEF DESCRIPTION OF THE DRAWINGS

The accompanying drawings, where like reference numerals refer to identical or functionally similar elements throughout the separate views, together with the detailed description below, are incorporated in and form part of the specification, and serve to further illustrate embodiments of concepts that include the claimed disclosure, and explain various principles and advantages of those embodiments.

FIG. 1 shows a schematic diagram illustrating a MTJ stack;

FIG. 2A shows a schematic diagram illustrating a MTJ stack where the free layer comprises a single magnetic layer;

FIG. 2B shows a schematic diagram illustrating a MTJ stack where the free layer comprises a synthetic anti-ferromagnet stack;

FIG. 3 shows a schematic diagram of an MTJ stack in which the free layer comprises three magnetic layers; in accordance with an embodiment of the present disclosure;

FIG. 4 shows a schematic diagram illustration a magnetic cancellation effect in the two-layer compared to a five-layer SAF free layer, in accordance with an embodiment of the present disclosure; and

FIG. 5 shows an electronic device which is using the nonvolatile magnetic memory, in accordance with an embodiment of the present disclosure.

The method and system have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

### DETAILED DESCRIPTION

In the following description, for purposes of explanation, numerous specific details are set forth in order to provide a thorough understanding of the disclosure. It will be apparent, however, to one skilled in the art, that the disclosure may be practiced without these specific details. In other instances, structures and devices are shown at block diagram form only in order to avoid obscuring the disclosure.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

Conventional MRAM configurations rely on an MTJ stack where the free layer is either a single magnetic layer or a synthetic anti-ferromagnet, which is composed of two ferromagnetic layers. The synthetic anti-ferromagnet free layer has the advantage over a single free layer of reducing edge domains and hence reducing variation in the switching field. The present invention modifies the free layer to a synthetic anti-ferromagnet with more than two ferromagnetic layers. This new change allows reducing both the magnitude and the variations of the switching field of the cell.

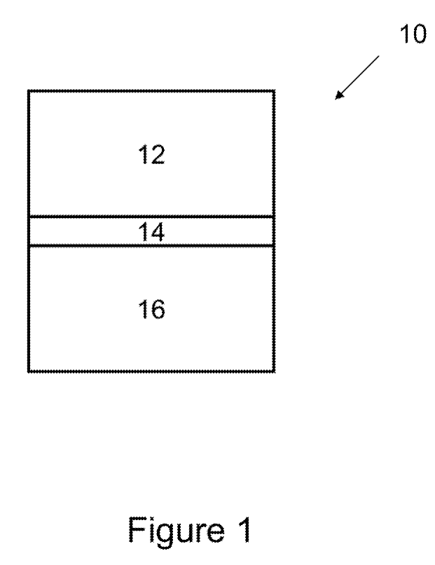

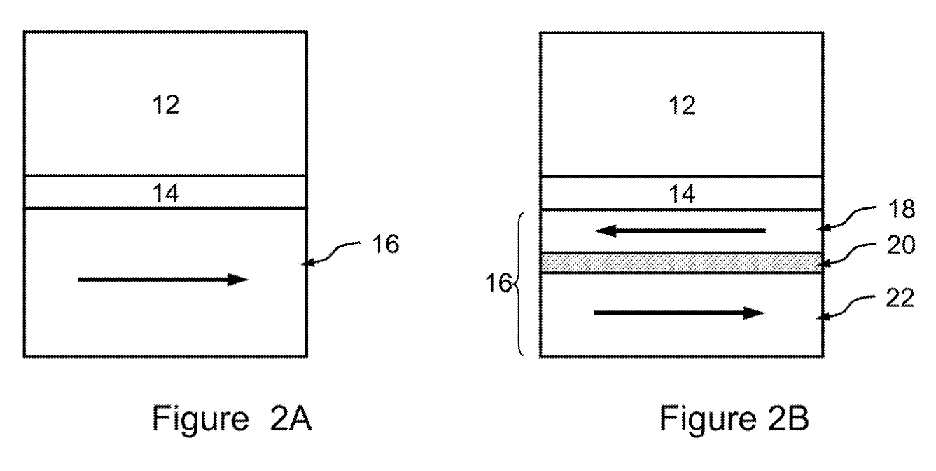

Referring to FIG. 1, a MTJ stack 10 is shown. The MTJ stack 10 has three distinctive ferromagnetic layers including a fixed layer 12, the tunnel oxide layer 14 and a free layer 16, as depicted schematically in FIG. 1. The free layer 16 and the fixed layer 12 may comprise different layers themselves. In one embodiment, the free layer 16 is composed of a single magnetic layer, as in FIG. 2A. In other embodiments the free layer 16 is composed of a synthetic anti-ferromagnet (SAF) stack 18-20-22, as shown in FIG. 2B. The SAF stack is formed when two thin ferromagnetic layers 18 and 22 in FIG. 2B are separated by a coupling layer 20 of certain thickness, which can be composed of different materials, including but not limited to Ru, Rh, Cr, V, Mo, Cu (preferably Ru). The ferromagnetic layers can be composed of Co, Fe, FeCo, FeCoB, or NiFe alloys or many other ferromagnetic materials.

In SAF, the magnetization in the ferromagnetic layers is coupled anti-ferromagnetically i.e. opposing each other, as suggested by the big arrows in FIG. 2B. The coupling is the result of exchange and magnetostatic forces between the layers. For MRAM purposes, one of the ferromagnetic layers of the SAF free layer 16 needs to have a higher magnetic moment than the other. One way to achieve that is to make one of the layers thicker than the other; as layer 22 is thicker than layer 18 in FIG. 2B. The SAF free layer 16 has the advantage over a single free layer of substantially reducing edge domains in the patterned MTJ cells. Consequently, SAF free layers tend to have less variation in switching field due to cell-to-cell shape variations. In other words, the SAF free layer 16 tends to be less sensitive to cell shape variations than a single free layer. Lower sensitivity to cell shape variations is very important for MRAM technology as the switching field variation problem tends to grow with decreasing cell size. Larger switching field variation negatively affects the margin for writing data in an MRAM device.

MRAM technology benefits not only from narrower switching field distribution but also from lower switching field, which also tends to grow with decreasing cell size. Embodiments of the present invention address both issues, making it possible to further reduce both factors. In one embodiment the SAF comprises a stack of more than two ferromagnetic layers where the contiguous ferromagnetic layers are separated by a coupling layers so that effectively a multilayer (at least three ferromagnetic layers) SAF is formed.

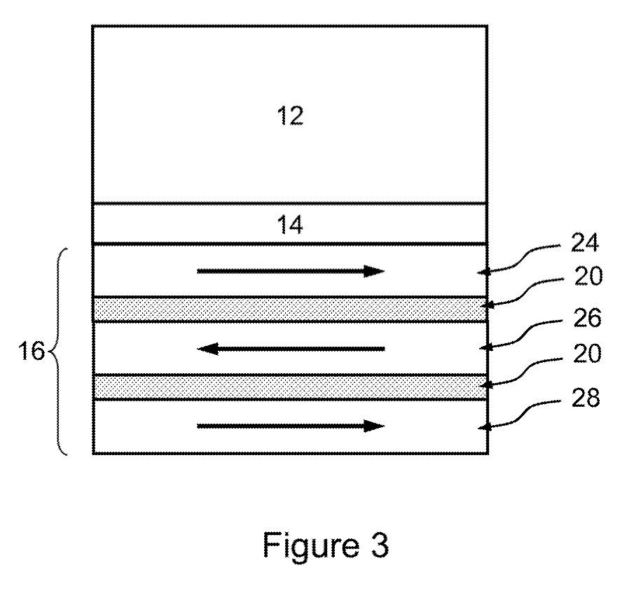

In one embodiment of the invention, the free layer 16 is composed of three ferromagnetic layers 24, 26 and 28; as depicted in FIG. 3. However, in another embodiment, the free layer 16 may be composed of at least three layers. The layers are anti-ferromagnetically coupled to the next with the assistance of coupling layers 20. The thicknesses of each ferromagnetic layer and the exchange coupling strength (because of layer 20) should be selected such that the anti-ferromagnetic structure is stable under normal circumstances of thermal loads and strayed fields.

In one embodiment of the invention using an odd number of ferromagnetic layers, the thicknesses of the magnetic layers are set the same, like in FIG. 3. That configuration is intrinsically stable provided the material of the magnetic layers is also the same. Advantageously with embodiments of the present invention, the switching field decreases with respect to the conventional SAF free layer (two ferromagnetic layers) because for a given net magnetization of the free layer the shape anisotropy is reduced by having the magnetic material divided into thinner layers. Another benefit of embodiments of the present invention is that for a given shape anisotropy a larger magnetization in the free layer is attained than in previous configurations. That translates to a lower switching field requirement.

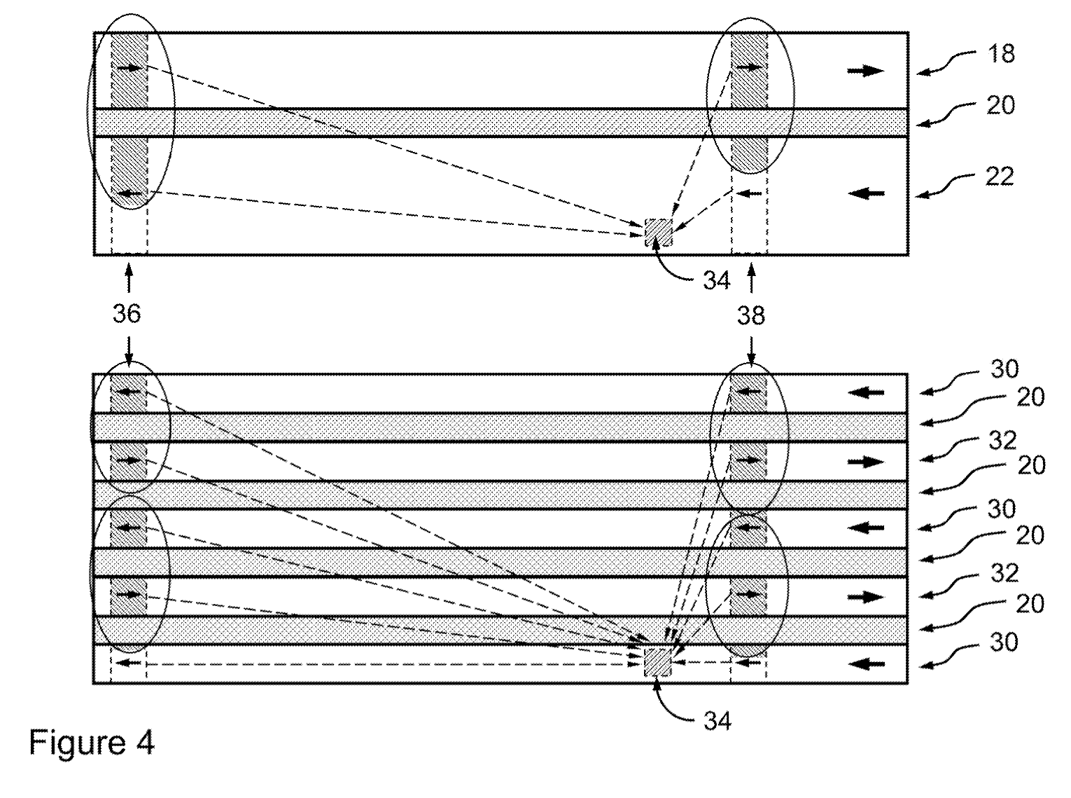

Graphically, this phenomenon is shown in FIG. 4 with the aid of a two-layer SAF (top) and a five-layer SAF (bottom). In FIG. 4, the thickness of layer 18 is equal to the sum of the thicknesses of the two layers 32, and that of layer 22 is equal to the sum of the thicknesses of the three layers 30. All other dimensions for layers 18, 20, 22, 30, and 32 are the same. The magnetization of each layer is indicated with a thick arrow to the right side of the layer. The net magnetization of both stacks is exactly the same. The magnetostatic interaction on a random block of magnetic material 34 can be analyzed by adding the contribution of all the magnetic layers on it. For illustration purposes consider two slabs of stack; one far apart 36 and the other relatively close 38.

Due to the anti-ferromagnetic magnetization of each layer relative to the next, the contribution froth each layer in the slab cancel out totally or at least partially, in the plane of the block 34 magnetization. The parts that cancel out each other totally are hatched and roughly enclosed in ovals. The parts that do not cancel out were left blank. The contribution from the slabs on block 34 is larger in the two-layer SAF than in the five-layer SAF, as in the former more magnetization is left un-canceled nearby block 34 than in the latter. The smaller the thicknesses difference between consecutive layers and the thinner the layers, the larger the cancellation effect is. This result can be generalized to any piece of magnetic material in the stack and it is the cause for lower magnetostatic anisotropy in the present invention. As the net magnetization of both stacks in FIG. 4 is the same, the Zeeman energy in the presence of an external magnetic field is also the same. However, the energy barrier for changing the net magnetization is lower for the new structure. Consequently, the new structure has lower switching field.

With respect to sensitivity to shape variations, the present invention intrinsically takes advantage of the synthetic anti-ferromagnetic SAF configuration. The proposed invention is in effect an expanded synthetic anti-ferromagnet where the edge domains problem is substantially less than in a single magnetic free layer. This is one cause of low shape variation sensitivity. Another cause is the smaller switching field compared to the conventional approaches. Smaller switching field means that any shape variation will have a smaller impact on the switching of the cell and hence on the switching field distribution. But lower shape sensitivity is not only because of lower switching field but also because for such thin layers, as required for MRAM, any irregular feature in the shape of the cell tends to encompass all the magnetic layers of the cell. As there is more cancellation taking place in the new structure than in the previous ones, the energy contribution of any feature added to the cell shape is lower in the present invention. Therefore, the five-layer SAF configuration is intrinsically less sensitive to variations in cell shape than conventional approaches.

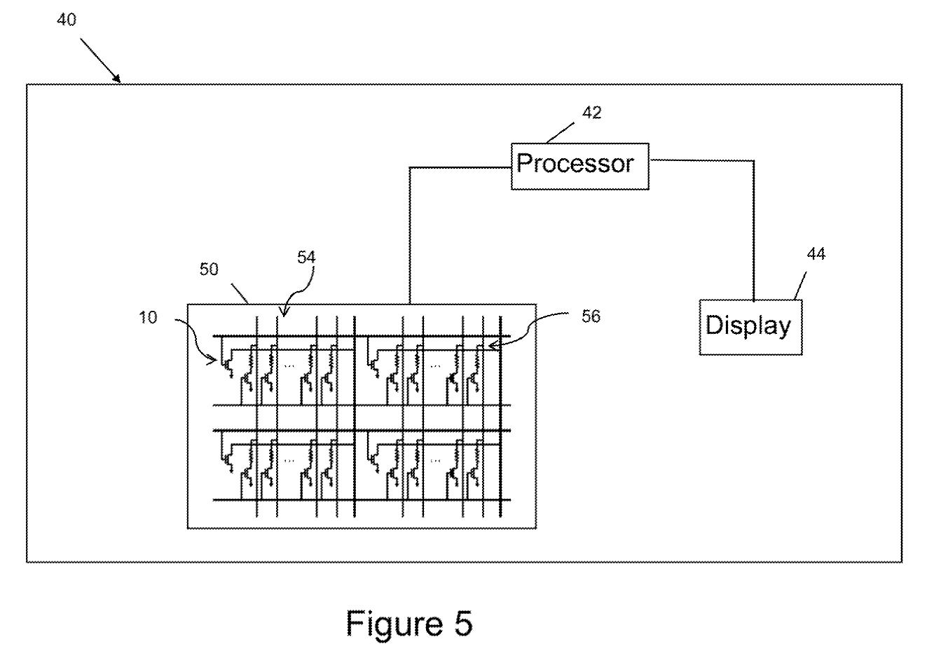

A MRAM memory array may be fabricated using the MTJ stack of the present invention. Further, a variety of electronic devices may be fabricated based on such a MRAM memory array. Referring now to FIG. 5, a block diagram of an electronic device 40 is shown as an example of a representative electronic device that may be fabricated, in accordance with embodiments of the present invention. The electronic device 40 may include a nonvolatile magnetic memory 50. The electronic device 40 further includes other components such as a processor 42 and a display 44 coupled to the MRAM 50. The MRAM 50 is in a form of array of MTJs 10. Further, the MRAM 50 is depicted in a form of a wiring diagram having bit lines 54 and word lines 56 to provide current to the MTJs. Examples of the electronic device 40 may include a digital camera, a mobile phone, a music device, and the like.

I/We claim:

1. A Magnetic Tunnel Junction (MTJ) stack usable in a nonvolatile magnetic memory array of MTJ stacks, the MTJ stack comprising:
a fixed ferromagnetic layer having its magnetic moment fixed in a preferred direction in the presence of an applied magnetic field caused by a current;
an insulating tunnel barrier layer in contact with the fixed ferromagnetic layer; and
a free ferromagnetic layer in contact with the insulating tunnel barrier layer, the free ferromagnetic layer comprising
a synthetic anti-ferromagnet (SAF) stack comprising
at least three ferromagnetic layers arranged anti-ferromagnetically relative to the next, and
at least two coupling layers, wherein the at least three ferromagnetic layers are separated by the at least two coupling layers.

2. The MTJ stack of claim 1, wherein each of the at least three ferromagnetic layers comprises at least one of a Co, Fe, FeCo, FeCoB, and NiFe alloy.

3. The MTJ stack of claim 1, wherein each of the at least two coupling layers comprises at least one of a Ru, Rh, Cr, V, Mo, and Cu.

4. The MTJ stack of claim 1, wherein each of the at least three ferromagnetic layers has a predefined thickness.

5. The MTJ stack of claim 1, wherein each of the at least two coupling layers has a predefined thickness.

6. The MTJ stack of claim 1, wherein the at least three ferromagnetic layers are odd in number such that a thickness and a material of each ferromagnetic layer is same.

7. A nonvolatile magnetic memory comprising:
an array of Magnetic Tunnel Junction (MTJ) stacks, wherein each Magnetic Tunnel Junction (MTJ) stack comprising
a fixed ferromagnetic layer having its magnetic moment fixed in a preferred direction in the presence of an applied magnetic field caused by a current,
an insulating tunnel barrier layer in contact with the fixed ferromagnetic layer, and
a free ferromagnetic layer in contact with the insulating tunnel barrier layer, the free ferromagnetic layer comprising
a synthetic anti-ferromagnet (SAF) stack comprising
at least three ferromagnetic layers arranged anti-ferromagnetically relative to the next, and
at least two coupling layers, wherein the at least three ferromagnetic layers are separated by the at least two coupling layers.

8. The nonvolatile magnetic memory of claim 7, wherein each of the at least three ferromagnetic layers is comprises at least one of a Co, Fe, FeCo, FeCoB, and NiFe alloy.

9. The nonvolatile magnetic memory of claim 7, wherein each of the at least two coupling layers comprises at least one of a Ru, Rh, Cr, V, Mo, and Cu.

10. The nonvolatile magnetic memory of claim 7, wherein each of the at least three ferromagnetic layers has a predefined thickness.

11. The nonvolatile magnetic memory of claim 7, wherein each of the at least two coupling layers has a predefined thickness.

12. The nonvolatile magnetic memory of claim 7, wherein the at least three ferromagnetic layers are odd in number such that a thickness and a material of each ferromagnetic layer is same.

13. An electronic device comprising:
a nonvolatile magnetic memory having an array of Magnetic Tunnel Junction (MTJ) stacks, wherein each Magnetic Tunnel Junction (MTJ) stack comprising
a fixed ferromagnetic layer having its magnetic moment fixed in a preferred direction in the presence of an applied magnetic field caused by a current,
an insulating tunnel barrier layer in contact with the fixed ferromagnetic layer, and
a free ferromagnetic layer in contact with the insulating tunnel barrier layer, the free ferromagnetic layer comprising
a synthetic anti-ferromagnet (SAF) stack comprising
at least three ferromagnetic layers arranged anti-ferromagnetically relative to the next, and
at least two coupling layers, wherein the at least three ferromagnetic layers are separated by the at least two coupling layers.

14. A method for fabricating an Magnetic Tunnel Junction (MTJ) stack comprising;
fabricating a fixed ferromagnetic layer having its magnetic moment fixed in a preferred direction in the presence of an applied magnetic field caused by a current,
fabricating an insulating tunnel barrier layer in contact with the fixed ferromagnetic layer, and
fabricating a free ferromagnetic layer in contact with the insulating tunnel barrier layer, the free ferromagnetic layer comprising
a synthetic anti-ferromagnet (SAF) stack comprising
at least three ferromagnetic layers arranged anti-ferromagnetically relative to the next, and
at least two coupling layers, wherein the at least three ferromagnetic layers are separated by the at least two coupling layers.

15. The method of claim 14, wherein each of the at least three ferromagnetic layers comprises of at least one of a Co, Fe, FeCo, FeCoB, and NiFe alloy.

16. The method of claim 14, wherein each of the at least two coupling layers comprise at least one of a Ru, Rh, Cr, V, Mo, and Cu.

17. The method of claim 14, wherein each of the at least three ferromagnetic layers has a predefined thickness.

18. The method of claim 14, wherein each of the at least two coupling layers has a predefined thickness.

19. The method of claim 14, wherein the at least three ferromagnetic layers are odd in number such that a thickness and a material of each ferromagnetic layer is same.
